(19) United States
(12) Patent Application Publication
(10) Pub. No.: US 2026/0333873 A1
(43) Pub. Date: Oct. 22, 2026

(54) WIRING SUBSTRATE AND DISPLAY DEVICE

(71) Applicant: Sharp Display Technology Corporation, Kameyama City (JP)

(72) Inventor: Hidetoshi NAKAGAWA, Kameyama City (JP)

(21) Appl. No.: 19/558,743

(22) Filed: Mar. 6, 2026

(30) Foreign Application Priority Data
Apr. 18, 2025 (JP) 2025-068582

(51) Int. Cl. H10D 86/40; G02F 1/1368; H10D 86/60

(52) U.S. Cl. CPC H10D 86/443; G02F 1/1368; H10D 86/60

(57) ABSTRACT

A wiring substrate includes a first line, a first terminal connected to an end of the first line, a first electrode, a first conductive portion, a first protection circuit connected to the first line and the first electrode, and a second protection circuit connected to the first line and the first conductive portion. A first resistance value that is a total of a line resistance from the first terminal to the first protection circuit and a circuit resistance of the first protection circuit is smaller than a second resistance value that is a total of a line resistance from the first terminal to the second protection circuit and a circuit resistance of the second protection circuit.

### CROSS REFERENCE TO RELATED APPLICATION

This application claims priority from Japanese Patent Application No. 2025-68582 filed on Apr. 18, 2025. The entire contents of the priority application are incorporated herein by reference.

### TECHNICAL FIELD

The present technology described herein relates to a wiring substrate and a display device with which electrostatic breakdown is less likely to occur in a second protection circuit.

### BACKGROUND

As one example of a wiring substrate included in a display device, a liquid crystal panel including an active matrix substrate as the wiring substrate has been known. Such a liquid crystal panel includes an active matrix substrate, a color filter substrate, and liquid crystal material. A transistor, a pixel electrode, signal lines, and backup lines for modifying defects of the signal lines are formed on the active matrix substrate. A common electrode (a counter electrode) is formed on the color filter substrate. The liquid crystal material is arranged between the active matrix substrate and the color filter substrate. The backup lines are (electrically) connected to the common electrode on the color filter substrate via a protection circuit, which is for releasing undesired charges generated in the backup lines, and a sealing member.

As another example, there has been known a liquid crystal display panel including a substrate for a display device as a wiring substrate. Such a liquid crystal display panel includes a repair line that is connected to a common potential supply conductive pattern via an electrostatic protection element portion. The repair line is for restoring a data bus line in which disconnection occurs. The electrostatic protection element portion includes first and second high resistance elements that are serially connected. A short circuit defect detecting line for detecting the short circuit in the repair line is connected to the connection point of the first and second high resistance elements.

The active matrix substrate of the one example includes a first protection circuit connected to two backup lines and a second protection circuit connected to one backup line of the two backup lines and the common electrode. A resistance value from the end of the one backup line to another backup line via the first protection circuit is about same as a resistance value from the end of the one backup line to the common electrode via the second protection circuit. Therefore, if electro static discharge (ESD) is input to the end of the one backup line, the ESD may be input to the first protection circuit and the second protection circuit. If the ESD is input to the first protection circuit, electrostatic breakdown occurs in the first protection circuit and after that, the two backup lines may not be protected.

In the substrate for a display device of the other example, the repair lines are connected to the short circuit defect detecting line via the first high resistance elements, respectively. The short circuit defect detecting line is connected to the common potential supply conductive pattern via the second high resistance element. A resistance value from the end of the short circuit defect detecting line to the repair lines via the first high resistance elements is about same as a resistance value from the end of the short circuit defect detecting line to the common potential supply conductive pattern via the second protection circuit. Therefore, if ESD is input to the end of the short circuit defect detecting line, the ESD may be input to the first high resistance elements and the second high resistance element. If the ESD is input to the first high resistance elements, electrostatic breakdown occurs in the first high resistance elements and after that, the repair lines may not be protected.

### SUMMARY

The technology described herein was made in view of the above circumstances. An object is to suppress occurrence of electrostatic breakdown in the second protection circuit.
(1) A wiring substrate according to the technology described herein includes a first line, a first terminal connected to an end of the first line, a first electrode, a first conductive portion, a first protection circuit connected to the first line and the first electrode, and a second protection circuit connected to the first line and the first conductive portion. A first resistance value that is a total of a line resistance from the first terminal to the first protection circuit and a circuit resistance of the first protection circuit is smaller than a second resistance value that is a total of a line resistance from the first terminal to the second protection circuit and a circuit resistance of the second protection circuit.
(2) In the wiring substrate, in addition to (1), the first protection circuit may be connected to a first connection portion of the first line and the second protection circuit may be connected to a second connection portion of the first line. The first connection portion may be closer to the first terminal than the second connection portion is.
(3) In the wiring substrate, in addition to (1) or (2), the number of connection portions of the first protection circuit and the first line may be greater than the number of connection portions of the second protection circuit and the first line.
(4) In the wiring substrate, in addition to any one of (1) to (3), the first protection circuit may include first protection circuit components and the second protection circuit includes second protection circuit components. The number of the first protection circuit components may be greater than the number of the second protection circuit components.
(5) In the wiring substrate, in addition to any one of (1) to (4), the first protection circuit may include a first protection circuit component and the second protection circuit may include a second protection circuit component. The first protection circuit component may include a first thin film transistor and a second thin film transistor. The first thin film transistor may include a gate electrode and a source electrode that are connected to the first line and a drain electrode that is connected to the first electrode. The second thin film transistor may include a gate electrode and a source electrode that are connected to the first electrode and a drain electrode that is connected to the first line. The second protection circuit component may include a third thin film transistor and a fourth thin film transistor. The third thin film transistor may include a gate electrode and a source electrode that are connected to the first line and a drain electrode that is connected to the first conductive portion. The fourth thin film transistor may include a gate electrode and a source electrode that are connected to the first conductive portion and a drain electrode that is connected to the first line. The first thin film transistor and the second thin film transistor may have a channel width greater than a channel width of the third thin film transistor and the fourth thin film transistor or the first thin film transistor and the second thin film transistor may have a channel length smaller than a channel length of the third thin film transistor and the fourth thin film transistor.
(6) In the wiring substrate, in addition to any one of (1) to (5), the first electrode may be an island electrode that is electrically isolated.
(7) The wiring substrate may further include, in addition to any one of (1) to (6), a second electrode that is kept at a predefined potential, and a condenser connected to the first electrode and the second electrode.
(8) The wiring substrate may further include, in addition to any one of (1) to (7), a second terminal that is connected to the first electrode and is supplied with a same signal as a signal that is supplied to the first terminal.
(9) A display device according to the technology described herein includes the wiring substrate according to any one of (1) to (8) and an opposed substrate disposed to face the wiring substrate.

According to the technology described herein, electrostatic breakdown is less likely to occur in the second protection circuit.

### BRIEF DESCRIPTION OF THE DRAWINGS

FIG. 1 is a plan view illustrating a liquid crystal panel, a driver, and a flexible substrate according to a first embodiment.

FIG. 2 is a cross-sectional view illustrating the liquid crystal panel, the driver, and the flexible substrate according to the first embodiment.

FIG. 3 is a circuit diagram illustrating an electric configuration of an array substrate of the liquid crystal panel according to the first embodiment.

FIG. 4 is a circuit diagram illustrating connection relation of a gate driver line, protection circuits, and a common electrode according to the first embodiment.

FIG. 5 is a circuit diagram illustrating a circuit configuration of each of the protection circuits according to the first embodiment.

FIG. 6 is a circuit diagram illustrating connection relation of a gate driver line, protection circuits, and a common electrode according to a second embodiment.

FIG. 7 is a circuit diagram illustrating connection relation of a gate driver line, protection circuits, and a common electrode according to a third embodiment.

FIG. 8 is a circuit diagram illustrating connection relation of a gate driver line, protection circuits, and a common electrode according to a fourth embodiment.

FIG. 9 is a plan view illustrating a first protection circuit, a first gate driver line, and the common electrode according to the fourth embodiment.

FIG. 10 is a cross-sectional view of an array substrate according to the fourth embodiment taken along line x-x in FIG. 9.

FIG. 11 is a plan view illustrating a second protection circuit, the first gate driver line, and a second gate driver line according to the fourth embodiment.

FIG. 12 is a circuit diagram illustrating connection relation of a gate driver line, protection circuits, and an island electrode according to a fifth embodiment.

FIG. 13 is a circuit diagram illustrating connection relation of a gate driver line, protection circuits, and a first electrode according to a sixth embodiment.

FIG. 14 is a circuit diagram illustrating connection relation of a gate driver line, protection circuits, and a first electrode according to a seventh embodiment.

### DETAILED DESCRIPTION

### First Embodiment

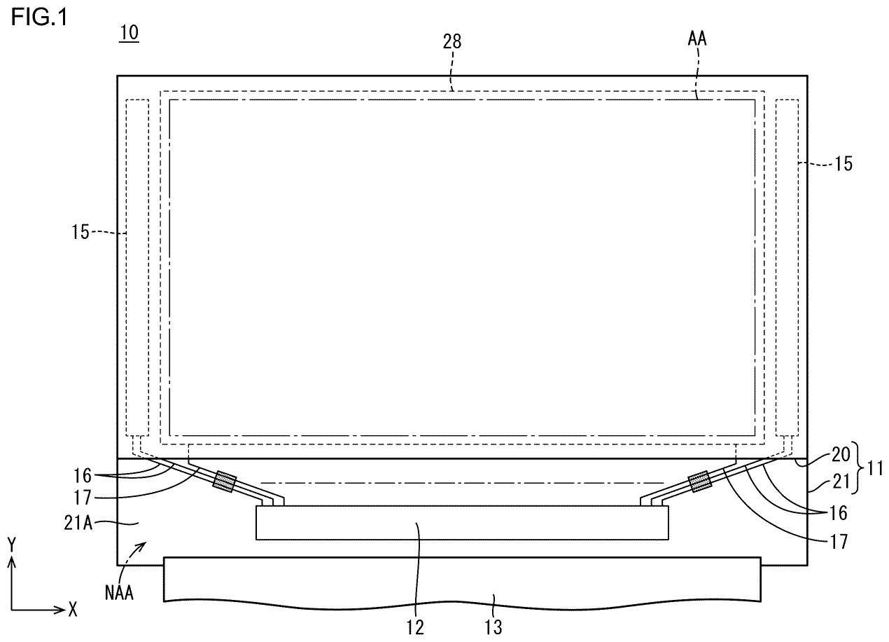

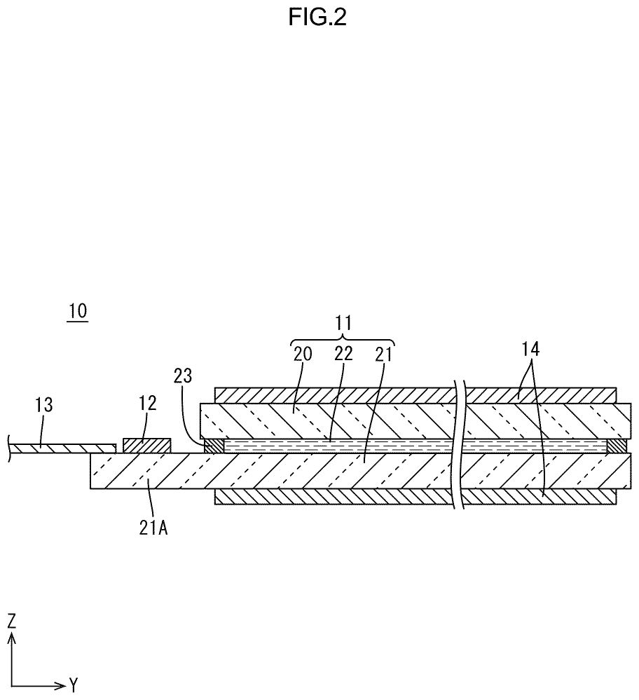

A first embodiment will be described with reference to FIGS. 1 to 5. In this embodiment section, a liquid crystal display apparatus 10 will be described. X-axes, Y-axes, and Z-axes may be present in the drawings. The axes in each drawing correspond to the respective axes in other drawings. An upper side and a lower side in FIG. 2 correspond to a front side and a back side, respectively.

As illustrated in FIG. 1, the liquid crystal display apparatus 10 at least includes a liquid crystal panel 11 (a display device, a display panel) that has a laterally long rectangular plan view shape and displays an image and a backlight unit (a lighting device) that supplies light to the liquid crystal panel 11 for displaying. The backlight unit is disposed behind (on a back surface side of) the liquid crystal panel 11. The backlight unit includes light sources configured to emit white light (e.g., LEDs) and optical members for converting the light from the light sources into planar light by applying optical effects to the light from the light sources. A middle section of a plate surface of the liquid crystal panel 11 is configured as a display area AA in which images are displayed. An outer section in a frame shape surrounding the display area AA on the plate surface of the liquid crystal panel 11 is configured as a non-display area NAA in which the images are not displayed.

The liquid crystal panel 11 will be described in detail with reference to FIGS. 1 and 2. As illustrated in FIGS. 1 and 2, the liquid crystal panel 11 includes a pair of substrates 20, 21 that are bonded to each other. One of the substrates 20, 21 on the front side is an opposed substrate 20 and another one on the back side is an array substrate 21 (a wiring substrate). The opposed substrate 20 and the array substrate 21 include glass substrates (light transmissive substrates) and various kinds of films that are formed in layers on an inner surface side of the glass substrates. A liquid crystal layer 22 is disposed between the substrates 20 and 21. The liquid crystal layer 22 includes liquid crystal molecules having optical characteristics that vary according to application of electric field. A sealing portion 23 is disposed between the outer peripheral portions of the substrates 20, 21 for sealing the liquid crystal layer 22. The sealing portion 23 is formed in a square frame shape and surrounds the liquid crystal layer 22. Polarizing plates 14 are attached to outer surfaces of the substrates 20 and 21.

As illustrated in FIGS. 1 and 2, the opposed substrate 20 has a short-side dimension that is smaller than a short-side dimension of the array substrate 21. The opposed substrate 20 is bonded to the array substrate 21 such that one of the long sides of the opposed substrate 20 is aligned with a corresponding one of the long sides of the array substrate 21. Therefore, a long side edge section including another one of the long sides of the array substrate 21 projects from another one of the long sides of the opposed substrate 20 and a projecting long side edge section is an uncovered section 21A. An entire area of the uncovered section 21A is the non-display area NAA and a driver 12 and a flexible substrate 13 that are components for supplying various signals are mounted on the uncovered section 21A.

The driver 12 includes LSI chips including driver circuits therein. The driver 12 is mounted on the uncovered section 21A of the array substrate 21 through the chip-on-glass (COG) technology. As illustrated in FIGS. 1 and 2, the driver 12 is disposed between the flexible substrate 13 and the display area AA with respect to the Y-axis direction. The driver 12 includes bumps (terminals) that are connected to various kinds of terminal portions mounted on the uncovered section 21A of the array substrate 21 via an anisotropic conductive film. The driver 12 processes the various kinds of signals transmitted from the flexible substrate 13 and outputs the processed signals to the terminal portions on the array substrate 21. Thus, the driver 12 supplies various kinds of signals to source lines 27 of the array substrate 21. The flexible substrate 13 is for supplying signals from an external control board to the array substrate 21.

As illustrated in FIG. 1, gate driver circuits 15 (display circuit section) are disposed in the non-display area NAA of the array substrate 21. A pair of gate driver circuits 15 are disposed to sandwich the display area AA with respect to the X-axis direction. The gate driver circuit 15 is disposed in a belt shape area extending in the Y-axis direction. The gate driver circuits 15 are for supplying scan signals to gate lines 26, which will be described later, and are monolithically fabricated with using films on the array substrate 21. The scan signals have a potential higher than a threshold voltage of a TFT 24. The gate driver circuit 15 is a gate driver monolithic (GDM) circuit.

Gate driver lines 16 (a first line, a first conductive portion) for driving the gate driver circuits 15 are disposed in the non-display area NAA of the array substrate 21. The gate driver lines 16 extend in a fan shape from the mount area of the driver 12 to the gate driver circuits 15. One end portions of the gate driver lines 16 are connected to terminals (including a first terminal) disposed in the mount area of the driver 12 on the array substrate 21. Other end portions of the gate driver lines 16 are connected to the gate driver circuits 15. Clock signals and gate circuit driver control signals such as initializing signals output from the driver 12 are supplied to the gate driver circuits 15 through the gate driver lines 16.

As illustrated in FIG. 1, the array substrate 21 includes a common electrode 28 (a first electrode) that is disposed to overlap at least an entire area of the display area AA and common lines 17 that are connected to the common electrode 28. The common electrode 28 is disposed such that a middle section overlaps the entire area of the display area AA and a frame-shaped outer peripheral section is disposed in the non-display area NAA. The common lines 17 extend in a fan shape from the mount area of the driver 12 to the edge portions of the common electrode 28 with respect to the X-axis direction. One ends of the common lines 17 are connected to terminals disposed in the mount area of the driver 12 of the array substrate 21. Other ends of the common lines 17 are connected to the common electrode 28. Common potential signals (a reference potential signal) output from the driver 12 are supplied to the common electrode 28 through the common lines 17. The gate driver lines 16 and the common lines 17 are connected to protection circuits 30, 31 that are for protecting the gate driver lines 16 and the common lines 17 from electro static discharge (ESD). The protection circuits 30, 31 are disposed in areas illustrated with shading in FIG. 1.

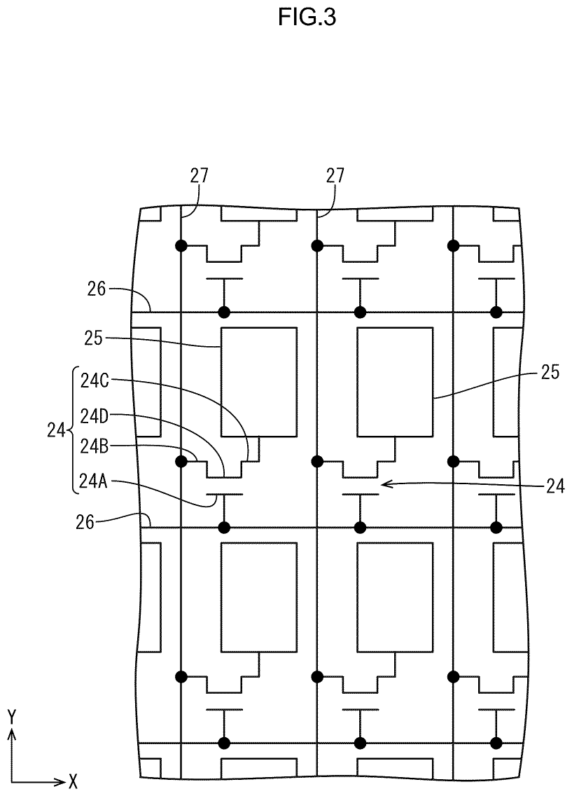

Next, a configuration of the array substrate 21 in the display area AA will be described with reference to FIG. 3. As illustrated in FIG. 3, at least TFTs 24 (thin film transistors, switching components) and pixel electrodes 25 are arranged on an inner surface of the array substrate 21 in the display area AA. The TFTs 24 and the pixel electrodes 25 are arranged at intervals in a matrix (rows and columns) along the X-axis direction and the Y-axis direction. Gate lines 26 (scan lines) and source lines 27 (image lines, signal lines) are routed perpendicular to each other (cross) to surround the TFTs 24 and the pixel electrodes 25. The gate lines 26 extend along the X-axis direction and are arranged at intervals with respect to the Y-axis direction. The source lines 27 extend along the Y-axis direction and are arranged at intervals with respect to the X-axis direction.

As illustrated in FIG. 3, the TFT 24 includes a gate electrode 24A connected to the gate line 26, a source electrode 24B connected to the source line 27, a drain electrode 24C connected to the pixel electrode 25, and a semiconductor section 24D. The TFTs 24 are driven based on scan signals supplied to the gate electrodes 24A through the gate lines 26. The scan signals include a potential higher than the threshold voltage of the TFTs 24 (a high level potential (Vgh)) and a potential lower than the threshold voltage (a low level potential Vgl)). Then, a channel section is created in the semiconductor section 24D. Therefore, the potential of the image signal supplied to the source electrode 24B through the source line 27 is supplied to the drain electrode 24C via the channel section of the semiconductor section 24D. As a result, the pixel electrode 25 is charged at the potential of the image signal. The pixel electrodes 25 are disposed to overlap the common electrode 28 with a space therebetween. A predefined electric field is applied to the liquid crystal layer 22 based on a potential difference created between the common electrode 28 and each pixel electrode 25 and the pixels perform display with a predetermined gradation.

Color filters are disposed in the display area AA of the opposed substrate 20 to be opposed to the pixel electrodes 25 on the array substrate 21 side. The color filters that exhibit three different colors of red (R), green (G), blue (B) are arranged repeatedly in a predefined order. The color filter and the corresponding pixel electrode 25 are configured as a pixel of each color (a red pixel, a green pixel, and a blue pixel). Three pixels of a red pixel, a green pixel, and a blue pixel are configured as a display pixel that can exert color display with a predetermined gradation. A light blocking portion (a black matrix) is disposed between the color filters in the display area AA of the opposed substrate 20 to prevent mixing of colors. Alignment films for orienting the liquid crystal molecules in the liquid crystal layer 22 are formed on innermost surfaces (in an uppermost layer) of the substrates 20 and 21 in contact with the liquid crystal layer 22.

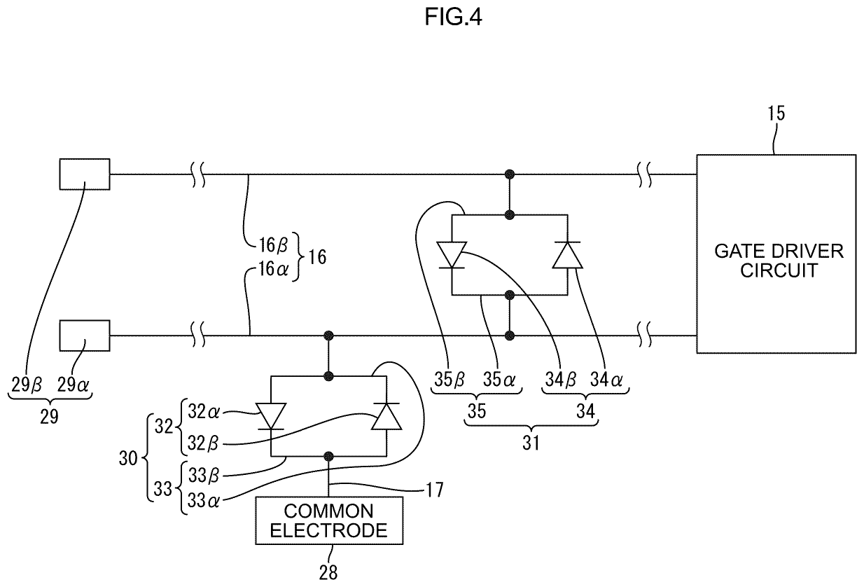

Next, two gate driver lines 16 including a first gate driver line 16α (a first line) and a second gate driver line 16β (a first conductive portion) and two protection circuits including a first protection circuit 30 and a second protection circuit 31 will be described with reference to FIG. 4. The two gate driver lines 16 are connected to the two protection circuits 30, 31, respectively. As illustrated in FIG. 4, the gate driver lines 16 are connected to two gate driver terminals 29 that are disposed in the mount area of the driver 12. The first protection circuit 30 is connected to the first gate driver line 16α and the common line 17. The second protection circuit 31 is connected to the first gate driver line 16α and the second gate driver line 16β. One ends of the first gate driver line 16α and the second gate driver line 16β are connected to the gate driver terminals 29, respectively, and other ends of the first gate driver line 16α and the second gate driver line 16β are connected to the gate driver circuit 15. The two gate driver terminals 29 include a first gate driver terminal 29α (a first terminal) connected to the first gate driver line 16α and a second gate driver terminal 29β connected to the second gate driver line 16β. The first gate driver terminal 29α and the second gate driver terminal 29β are supplied with signals output from the driver 12.

The first protection circuit 30 and the second protection circuit 31 are monolithically fabricated with using films included in the array substrate 21. As illustrated in FIG. 4, the first protection circuit 30 is connected to the first gate driver line 16α and the common line 17. The second protection circuit 31 is connected to the first gate driver line 16α and the second gate driver line 16β. The first protection circuit 30 is disposed between the first gate driver line 16α and the common line 17. The first protection circuit 30 is connected to the common electrode 28 via the common line 17. The first protection circuit 30 includes two first protection circuit components 32 and two first connection lines 33 that connect the two first protection circuit components 32. The first protection circuit components 32 include a first thin film transistor 32α and a second thin film transistor 32β. The second protection circuit 31 is disposed between the first gate driver line 16α and the second gate driver line 16β. The second protection circuit 31 includes two second protection circuit components 34 and two second connection lines 35 that connect the two second protection circuit components 34. The second protection circuit components 34 include a third thin film transistor 34α and a fourth thin film transistor 34β.

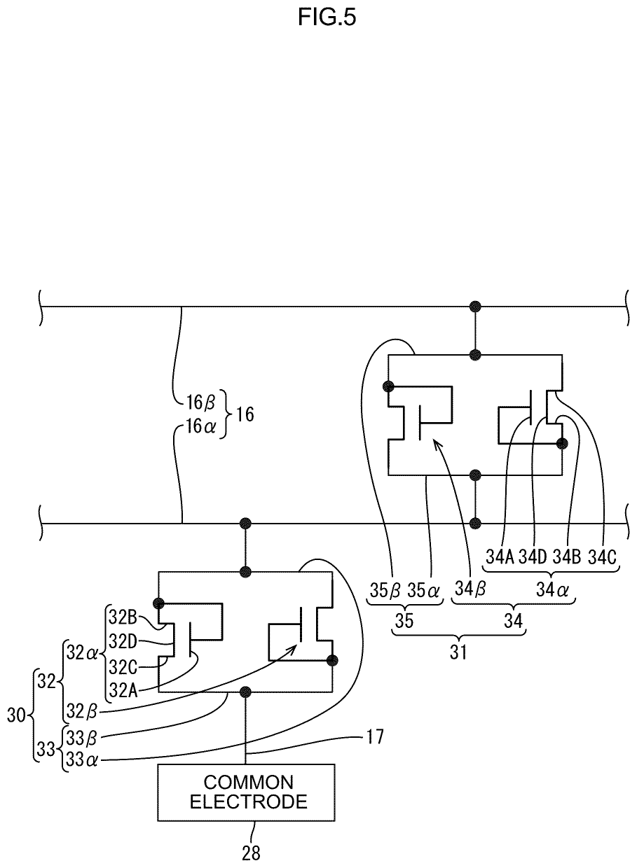

As illustrated in FIG. 5, each of the first thin film transistor 32α and the second thin film transistor 32β of the first protection circuit components 32 includes a gate electrode 32A, a source electrode 32B, a drain electrode 32C, and a semiconductor section 32D. Each of the first thin film transistor 32α and the second thin film transistor 32β is a diode including the gate electrode 32A and the source electrode 32B that are connected as an anode and the drain electrode 32C as a cathode. The first connection lines 33 include a first connection line 33α and a first connection line 33β. The first connection line 33α is connected to the gate electrode 32A and the source electrode 32B of the first thin film transistor 32α, the drain electrode 32C of the second thin film transistor 32β, and the first gate driver line 16α. The first connection line 33β is connected to the drain electrode 32C of the first thin film transistor 32α, the gate electrode 32A and the source electrode 32B of the second thin film transistor 32β, and the common line 17. Thus, the first protection circuit 30 is a diode ring including the two first protection circuit components 32 that are diodes and connected via the two first connection lines 33.

As illustrated in FIG. 5, each of the third thin film transistor 34α and the fourth thin film transistor 34β of the second protection circuit components 34 includes a gate electrode 34A, a source electrode 34B, a drain electrode 34C, and a semiconductor section 34D. Each of the third thin film transistor 34α and a fourth thin film transistor 34β is a diode including the gate electrode 34A and the source electrode 34B that are connected as an anode and the drain electrode 34C as a cathode. The second connection lines 35 include a second connection line 35α and a second connection line 35β. The second connection line 35α is connected to the gate electrode 34A and the source electrode 34B of the third thin film transistor 34α, the drain electrode 34C of the fourth thin film transistor 34β, and the first gate driver line 16α. The second connection line 34β is connected to the drain electrode 34C of the third thin film transistor 34α, the gate electrode 34A and the source electrode 34B of the fourth thin film transistor 34β, and the second gate driver line 16β. Thus, the second protection circuit 31 is a diode ring including the two second protection circuit components 34 that are diodes and connected via the two second connection lines 35.

As illustrated in FIG. 4, the protection circuits 30, 31 are connected via the gate driver lines 16; however, a current does not flow through the protection circuits 30, 31 with a voltage of signals transferred through the gate driver lines 16. Therefore, the signal supplied to the first gate driver line 16α is not supplied to the second gate driver line 16β and the potential of the first gate driver line 16α does not become same as that of the common electrode 28 through the common line 17. A current flows through the protection circuits 30, 31 with a voltage higher than the voltage of the signal transferred through the gate driver lines 16 such as a high voltage caused by the ESD. The protection circuits 30, 31 are for attenuation of the high voltage. Therefore, if a high voltage is input to one of the gate driver lines 16 due to the ESD, the high voltage is attenuated by the protection circuit 30, 31 and released to the common electrode 28 via the common line 17. Accordingly, electrostatic breakdown is less likely to occur in the gate driver circuit 15, which is connected to the gate driver lines 16, due to a high voltage caused by the ESD.

As illustrated in FIGS. 4 and 5, a first resistance value R1 is smaller than a second resistance value R2. The first resistance value R1 is a total of a first line resistance rw1 that is a line resistance from the first gate driver terminal 29α to the first protection circuit 30 and a first circuit resistance rc1 that is a circuit resistance of the first protection circuit 30. The second resistance value R2 is a total of a second line resistance rw2 that is a line resistance from the first gate driver terminal 29α to the second protection circuit 31 and a second circuit resistance rc2 that is a circuit resistance of the second protection circuit 31. If the first resistance value R1 is equal to the second resistance value R2 and a high voltage caused by the ESD is input to the first gate driver terminal 29α, the high voltage is input to both of the first protection circuit 30 and the second protection circuit 31. If the ESD is input to the second protection circuit 31, electrostatic breakdown may occur in the second protection circuit 31. In this respect, according to this embodiment, the first resistance value R1 is smaller than the second resistance value R2. Therefore, if a high voltage caused by the ESD is input to the first gate driver terminal 29α, the high voltage is transferred to the common electrode 28 via the first protection circuit 30 out of the two protection circuits 30, 31 that are connected to the first gate driver line 16α. Accordingly, electrostatic breakdown is less likely to occur in the second protection circuit 31 that is connected to the first gate driver line 16α and the second gate driver line 16β. Therefore, the first gate driver line 16α and the second gate driver line 16β can be surely protected by the second protection circuit 31 that is in a normal condition.

In this embodiment, as illustrated in FIGS. 4 and 5, a connection portion of the first gate driver line 16α (a first connection portion) that is connected to the first protection circuit 30 is closer to the first gate driver terminal 29α than a connection portion of the first gate driver line 16α (a second connection portion) that is connected to the second protection circuit 31. Specifically, the connection portion of the first gate driver line 16α that is connected to the first connection line 33α of the first protection circuit 30 is closer to the first gate driver terminal 29α than the connection portion of the first gate driver line 16α that is connected to the second connection line 35α of the second protection circuit 31 is by at least 5 mm or more. According to such a configuration, the first line resistance rw1 from the first gate driver terminal 29α to the first protection circuit 30 can be effectively lower than the second line resistance rw2 from the first gate driver terminal 29α to the second protection circuit 31. Accordingly, the first resistance value R1 can be effectively smaller than the second resistance value R2 and electrostatic breakdown is less likely to occur in the second protection circuit 31.

As previously described, the array substrate 21 (the wiring substrate) of this embodiment includes the first gate driver line 16α (the first line), the first gate driver terminal 29α (the first terminal) connected to an end of the first gate driver line 16α, the common electrode 28 (the first electrode), the second gate driver line 16β (the first conductive portion), the first protection circuit 30 connected to the first gate driver line 16α and the common electrode 28, and the second protection circuit 31 connected to the first gate driver line 16α and the second gate driver line 16β. The first resistance value R 1 is smaller than the second resistance value R2. The first resistance value R1 is a total of the first line resistance rw1 that is a line resistance from the first gate driver terminal 29α to the first protection circuit 30 and the first circuit resistance rc1 that is a circuit resistance of the first protection circuit 30. The second resistance value R2 is a total of the second line resistance rw2 that is a line resistance from the first gate driver terminal 29α to the second protection circuit 31 and the second circuit resistance rc2 that is a circuit resistance of the second protection circuit 31.

The first resistance value R1 is smaller than the second resistance value R2. Therefore, with a high voltage caused by the ESD being input to the first gate driver terminal 29α, the high voltage is transferred to the common electrode 28 via the first protection circuit 30 out of the first protection circuit 30 and the second protection circuit 31 that are connected to the first gate driver line 16α. Accordingly, electrostatic breakdown is less likely to occur in the second protection circuit 31 that is connected to the first gate driver line 16α and the second gate driver line 16β. Therefore, the first gate driver line 16α and the second gate driver line 16β can be surely protected by the second protection circuit 31 that is in a normal condition.

The connection portion of the first gate driver line 16α that is connected to the first protection circuit 30 is closer to the first gate driver terminal 29α than the connection portion of the first gate driver line 16α that is connected to the second protection circuit 31 is. According to such a configuration, the first line resistance rw1 from the first gate driver terminal 29α to the first protection circuit 30 can be effectively lower than the second line resistance rw2 from the first gate driver terminal 29α to the second protection circuit 31. Accordingly, the first resistance value R1 can be effectively smaller than the second resistance value R2 and electrostatic breakdown is less likely to occur in the second protection circuit 31.

The liquid crystal panel 11 (the display device) of this embodiment includes the array substrate 21 and the opposed substrate 20 that is opposed to the array substrate 21. According to such a liquid crystal panel 11, electrostatic breakdown is less likely to occur in the second protection circuit 31 and therefore the production yield of the liquid crystal panel 11 can be improved. <Second Embodiment>

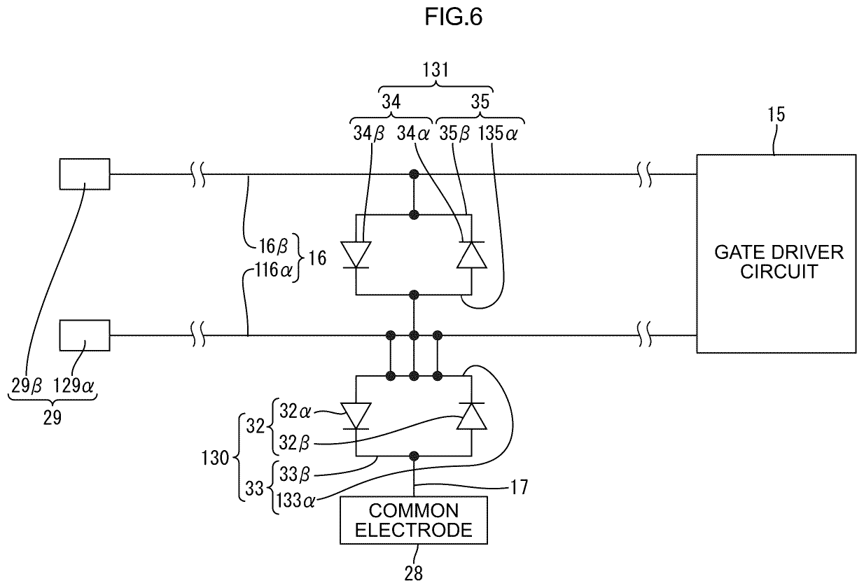

A second embodiment will be described with reference to FIG. 6. The second embodiment differs from the first embodiment in a configuration of a first protection circuit 130. Configurations, operations, and effects similar to those of the first embodiment may not be described.

As illustrated in FIG. 6, the number of connection portions of a first gate driver line 116α and the first protection circuit 130 is greater than the number of connection portions of the first gate driver line 116α and a second protection circuit 131. Specifically, the number of connection portions of a first connection line 133α of the first protection circuit 130 and the first gate driver line 116α is three and the number of the connection portions of a second connection line 135α of the second protection circuit 131 and the first gate driver line 116α is one. According to such a configuration, the first line resistance rw1 from a first gate driver terminal 129α to the first protection circuit 130 can be effectively lower than the second line resistance rw2 from the first gate driver terminal 129α to the second protection circuit 131. Accordingly, the first resistance value R1 can be effectively smaller than the second resistance value R2 and electrostatic breakdown is less likely to occur in the second protection circuit 131. The connection position of the first connection line 133α of the first protection circuit 130 and the first gate driver line 116α is substantially same as the connection position of the second connection line 135α of the second protection circuit 131 and the first gate driver line 116α.

As previously described, according to this embodiment, the number of connection portions of the first protection circuit 130 and the first gate driver line 116α is greater than the number of connection portions of the second protection circuit 131 and the first gate driver line 116α. According to such a configuration, the first line resistance rw1 from the first gate driver terminal 129α to the first protection circuit 130 can be effectively lower than the second line resistance rw2 from the first gate driver terminal 129α to the second protection circuit 131. Accordingly, the first resistance value R1 can be effectively smaller than the second resistance value R2 and electrostatic breakdown is less likely to occur in the second protection circuit 131.

### Third Embodiment

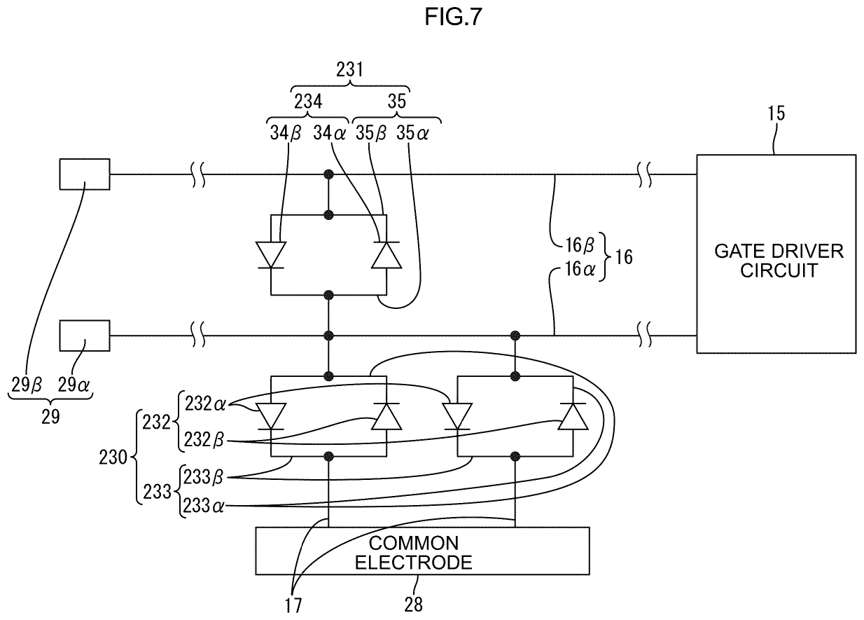

A third embodiment will be described with reference to FIG. 7. The third embodiment differs from the first embodiment in the number of first protection circuit components 232. Configurations, operations, and effects similar to those of the first embodiment may not be described.

As illustrated in FIG. 7, a first protection circuit 230 includes four first protection circuit components 232 that are configured as two diode rings. Specifically, the first protection circuit 230 includes two first thin film transistors 232α and two second thin film transistors 232β as the first protection circuit components 232 and two first connection lines 233α and two first connection lines 233β that connect the first thin film transistors 232α and the second thin film transistors 232β. Namely, the number of first protection circuit components 232 included in the first protection circuit 230 is greater than the number of second protection circuit components 234 included in the second protection circuit 231. According to such a configuration, the first circuit resistance rc1 of the first protection circuit 230 including the greater number of first protection circuit components 232 than the second protection circuit components 234 can be effectively lower than the second circuit resistance rc2 of the second protection circuit 231 including the second protection circuit component 234. Accordingly, the first resistance value R1 can be effectively smaller than the second resistance value R2 and electrostatic breakdown is less likely to occur in the second protection circuit 231.

As previously described, according to this embodiment, the first protection circuit 230 includes the first protection circuit components 232 and the second protection circuit 231 includes the second protection circuit components 234. The number of first protection circuit components 232 (232α, 232β) included in the first protection circuit 230 is greater than the number of second protection circuit components 234 (34α, 34β) included in the second protection circuit 231. According to such a configuration, the first circuit resistance rc1 of the first protection circuit 230 including the greater number of first protection circuit components 232 than the number of second protection circuit components 234 can be effectively lower than the second circuit resistance rc2 of the second protection circuit 231 including the second protection circuit components 234. Accordingly, the first resistance value R1 can be effectively smaller than the second resistance value R2 and electrostatic breakdown is less likely to occur in the second protection circuit 231.

### Fourth Embodiment

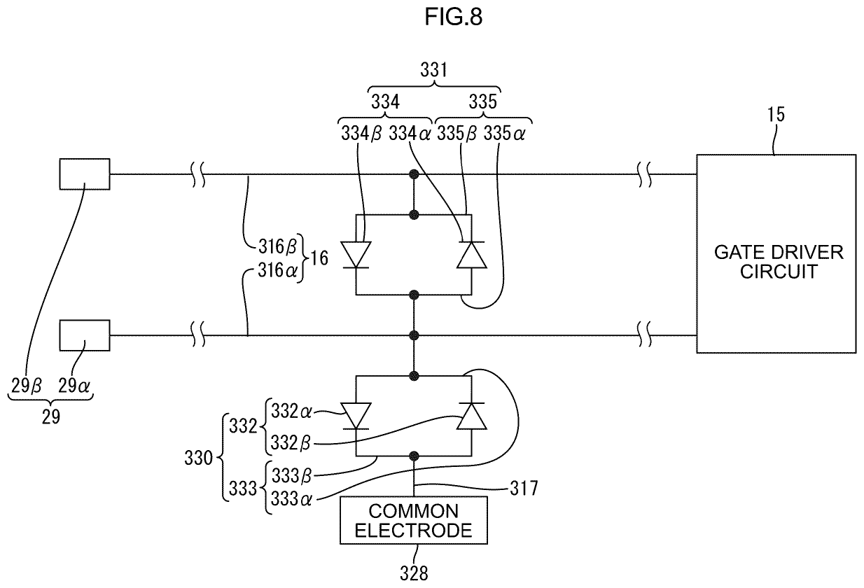

A fourth embodiment will be described with reference to FIGS. 8 to 11. The fourth embodiment differs from the first embodiment in a configuration of a first protection circuit component 332. Configurations, operations, and effects similar to those of the first embodiment may not be described.

In this embodiment, as illustrated in FIG. 8, similar to the second embodiment, the connection position of a first connection line 333α of a first protection circuit 330 and a first gate driver line 316α is substantially same as the connection position of a second connection line 335α of a second protection circuit 331 and the first gate driver line 316α.

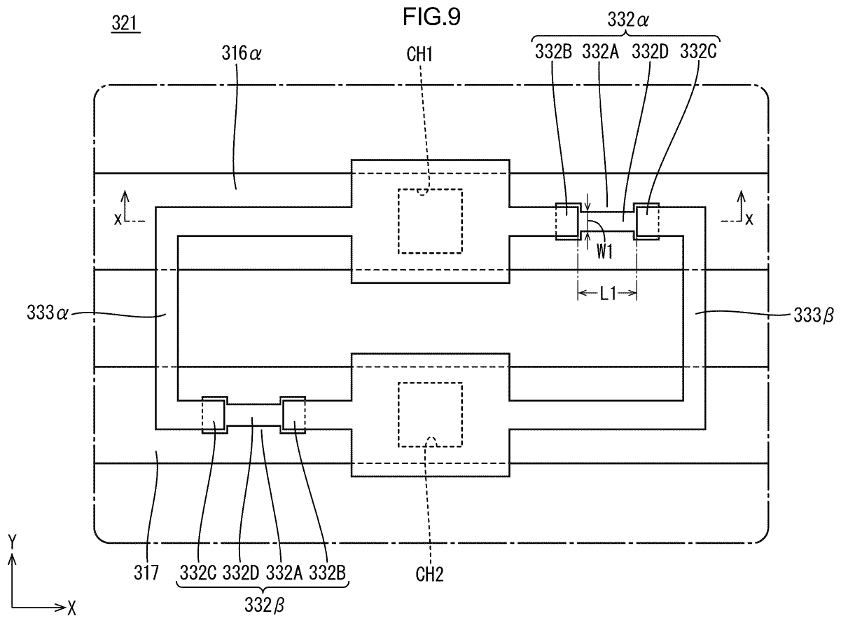

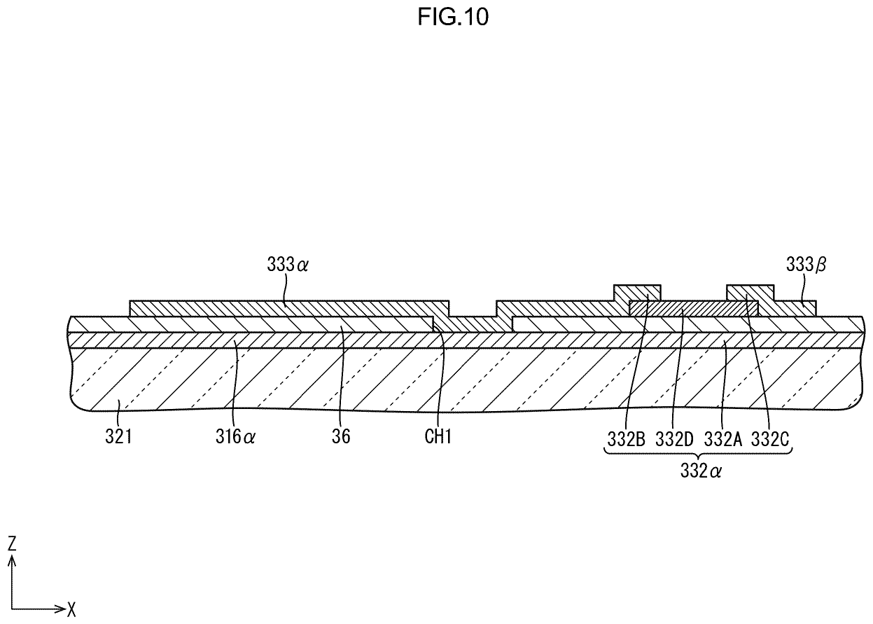

As illustrated in FIG. 9, the first protection circuit component 332 of the first protection circuit 330 of this embodiment is disposed to overlap the first gate driver line 316α and the common line 317. Films of an array substrate 321 will be described with reference to FIG. 10. As illustrated in FIG. 10, on the glass substrate of the array substrate 321, at least a first metal film, a gate insulating film 36, a semiconductor film, and a second metal film are disposed on top of each other from a lower layer side. Portions of the first metal film are configured as the first gate driver line 316α, the common line 317, and the gate electrodes 332A, 334A of thin film transistors 332α, 332β, 334α, 334β. Portions of the semiconductor film are configured as semiconductor sections 332D, 334D of the thin film transistors 332α, 332β, 334α, 334β. Portions of the second metal film are configured as connection lines 333, 335 and source electrodes 332B, 334B and drain electrodes 332, 334C of the thin film transistors 332α, 332β, 334α, 334β.

As illustrated in FIG. 10, in each of the thin film transistors 332α, 332β included in the first protection circuit component 332, the semiconductor section 332D is disposed to overlap the gate electrode 332A via the gate insulating film 36. As illustrated in FIG. 9, the gate electrode 332A of the first thin film transistors 332α is a portion of the first gate driver line 316α. The gate electrode 332A of the second thin film transistor 332β is a portion of the common line 317. The semiconductor sections 332D extend along the X-axis direction and along the direction in which the first gate driver line 316α and the common line 317 extend. The source electrode 332B and the drain electrode 332C of each of the first thin film transistor 332α and the second thin film transistor 332β are directly contacted with and connected to the semiconductor section 332D with being spaced from each other. The source electrode 332B and the drain electrode 332C are directly continuous and connected to the first connection lines 333, respectively. The first connection line 333α is disposed to overlap the first gate driver line 316α and connected to the first gate driver line 316α via a first contact hole CH1 formed in the gate insulating film 36 that is disposed between the first connection line 333α and the first gate driver line 316α. The source electrode 332B of the first thin film transistor 332α is connected to the first gate driver line 316α via the first connection line 333α. As illustrated in FIG. 9, a first connection line 333β is disposed to overlap the common line 317 and connected to the common line 317 via a second contact hole CH2 formed in the gate insulating film 36 that is disposed between the first connection line 333β and the common line 317. The source electrode 332B of the second thin film transistor 332β is connected to the common line 317 via the first connection line 333β.

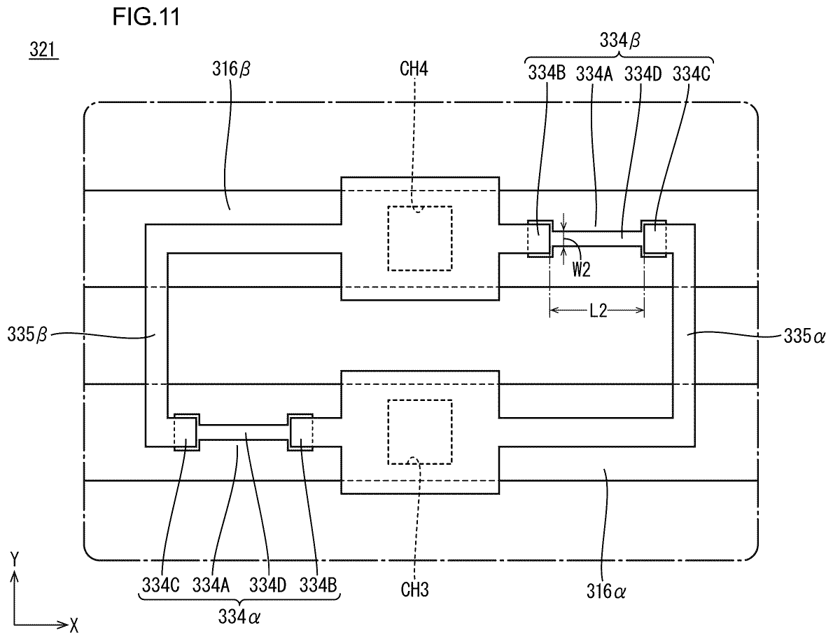

As illustrated in FIG. 11, in each of the third thin film transistor 334α and the fourth thin film transistor 334β of the second protection circuit component 334, the semiconductor section 334D is disposed to overlap the gate electrode 334A via the gate insulating film 36. The gate electrode 334A of the third thin film transistors 334α is a portion of the first gate driver line 316α. The gate electrode 334A of the fourth thin film transistor 334β is a portion of the second gate driver line 316β. The semiconductor sections 334D extend along the X-axis direction and along the direction in which the first gate driver line 316α and the second gate driver line 316β extend. The source electrode 334B and the drain electrode 334C of each of the third thin film transistor 334α and the fourth thin film transistor 334β are directly contacted with and connected to the semiconductor section 334D with being spaced from each other. The source electrode 334B and the drain electrode 334C are directly continuous and connected to the second connection lines 335, respectively. The second connection line 335α is disposed to overlap the first gate driver line 316α and connected to the first gate driver line 316α via a third contact hole CH3 formed in the gate insulating film 36 that is disposed between the second connection line 335α and the first gate driver line 316α. The source electrode 334B of the third thin film transistor 334α is connected to the first gate driver line 316α via the second connection line 335α. The second connection line 335β is disposed to overlap the second gate driver line 316β and connected to the second gate driver line 316β via a fourth contact hole CH4 formed in the gate insulating film 36 that is disposed between the second connection line 335β and the second gate driver line 316β. The source electrode 334B of the fourth thin film transistor 334β is connected to the second gate driver line 316β via the second connection line 335β.

In this embodiment, the configuration of the semiconductor section 332D of the first protection circuit component 332 differs from the configuration of the semiconductor section 334D of the second protection circuit component 334. The semiconductor sections 332D of the first thin film transistor 332α and the second thin film transistor 332β have a channel length L1 and a channel width W1. The semiconductor sections 334D of the third thin film transistor 334α and the fourth thin film transistor 334β have a channel length L2 and a channel width W2. The channel length corresponds to a length of a channel area created in the semiconductor section 332D, 334D and the distance from the source electrode 332B, 334B to the drain electrode 332C, 334C is defined as the channel length. The width of the channel area created in the semiconductor section 332D, 334D is defined as the channel width.

As illustrated in FIGS. 9 and 11, the channel length L1 of the first thin film transistor 332α and the second thin film transistor 332β is smaller than the channel length L2 of the third thin film transistor 334α and the fourth thin film transistor 334β. The channel width W1 of the first thin film transistor 332α and the second thin film transistor 332β is greater than the channel width W2 of the third thin film transistor 334α and the fourth thin film transistor 334β. With such a configuration, the first circuit resistance rc1 of the first protection circuit 330, which includes the first thin film transistor 332α and the second thin film transistor 332β as the first protection circuit component 332, is lower than the second circuit resistance rc2 of the second protection circuit 331, which includes the third thin film transistor 334α and the fourth thin film transistor 334β as the second protection circuit component 334. Accordingly, the first resistance value R1 is lower than the second resistance value R2 and therefore, the high voltage caused by the ESD is likely to be input to the first protection circuit 330 than the second protection circuit 331.

With the high voltage caused by the ESD being input to the first protection circuit 330, the first thin film transistor 332α including the gate electrode 332A and the source electrode 332B that are connected to the first gate driver line 316α as illustrated in FIG. 9 is driven. Then, in the first thin film transistor 332α, the high voltage is input from the source electrode 332B to the drain electrode 332C. The drain electrode 332C of the first thin film transistor 332α is connected to the gate electrode 332A and the source electrode 332B of the second thin film transistor 332β. Therefore, the second thin film transistor 332β is driven by the high voltage that is input to the drain electrode 332C of the first thin film transistor 332α and the high voltage is input from the source electrode 332B to the drain electrode 332C of the second thin film transistor 332β. The drain electrode 332C of the first thin film transistor 332α is connected to the common electrode 328 via the common line 317. Therefore, the high voltage is released to the common electrode 328 through the common line 317. Thus, the high voltage caused by the ESD is less likely to be input to the second protection circuit 331 and therefore, electrostatic breakdown is less likely to occur in the second protection circuit 331.

As previously described, according to this embodiment, the first protection circuit 330 includes the first protection circuit component 332 and the second protection circuit 331 includes the second protection circuit component 334. The first protection circuit component 332 includes the first thin film transistor 332α and the second thin film transistor 332β. The first thin film transistor 332α includes the gate electrode 332A and the source electrode 332B, which are connected to the first gate driver line 316α, and the drain electrode 332C, which is connected to the common electrode 328. The second thin film transistor 332β includes the gate electrode 332A and the source electrode 332B, which are connected to the common electrode 328, and the drain electrode 332C, which is connected to the first gate driver line 316α. The second protection circuit component 334 includes the third thin film transistor 334α and the fourth thin film transistor 334β. The third thin film transistor 334α includes the gate electrode 334A and the source electrode 334B, which are connected to the first gate driver line 316α, and the drain electrode 334C, which is connected to the second gate driver line 316β. The fourth thin film transistor 334β includes the gate electrode 334A and the source electrode 334B, which are connected to the second gate driver line 316β, and the drain electrode 334C, which is connected to the first gate driver line 316α. The first thin film transistor 332α and the second thin film transistor 332β have a channel width that is greater than a channel width of the third thin film transistor 334α and the fourth thin film transistor 334β or the first thin film transistor 332α and the second thin film transistor 332β have a channel length that is smaller than a channel length of the third thin film transistor 334α and the fourth thin film transistor 334β. With such a configuration, the first circuit resistance rc1 of the first protection circuit 330, which includes the first thin film transistor 332α and the second thin film transistor 332β as the first protection circuit component 332, is lower than the second circuit resistance rc2 of the second protection circuit 331, which includes the third thin film transistor 334α and the fourth thin film transistor 334β as the second protection circuit component 334. Accordingly, the first resistance value R1 is lower than the second resistance value R2 and therefore, the high voltage caused by the ESD is likely to be input to the first protection circuit 330 than the second protection circuit 331. With the high voltage caused by the ESD being input to the first protection circuit 330, the first thin film transistor 332α including the gate electrode 332A and the source electrode 332B that are connected to the first gate driver line 316α as illustrated in FIG. 9 is driven. Then, in the first thin film transistor 332α, the high voltage is input from the source electrode 332B to the drain electrode 332C. The drain electrode 332C of the first thin film transistor 332α is connected to the gate electrode 332A and the source electrode 332B of the second thin film transistor 332β. Therefore, the second thin film transistor 332β is driven by the high voltage that is input to the drain electrode 332C of the first thin film transistor 332α and the high voltage is input from the source electrode 332B to the drain electrode 332C of the second thin film transistor 332β. The drain electrode 332C of the first thin film transistor 332α is connected to the common electrode 328. Therefore, the high voltage is released to the common electrode 328. Thus, the high voltage caused by the ESD is less likely to be input to the second protection circuit 331 and therefore, electrostatic breakdown is less likely to occur in the second protection circuit 331.

### Fifth Embodiment

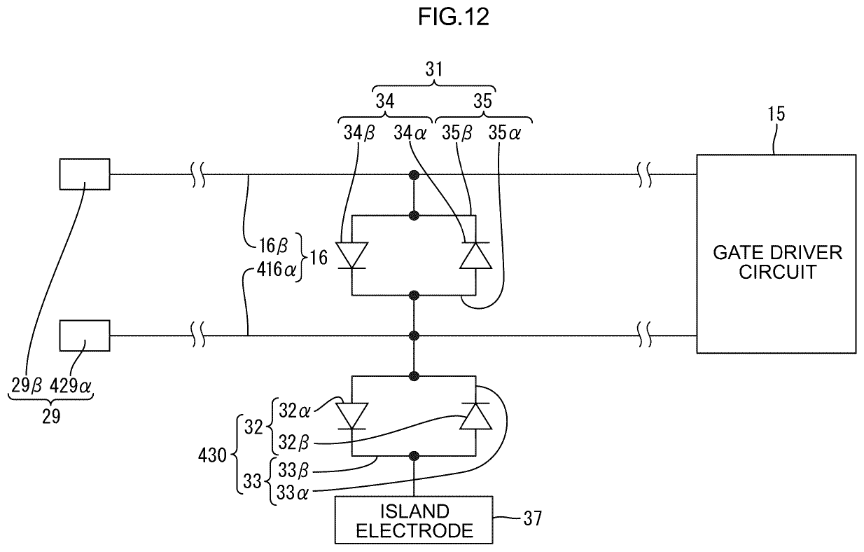

A fifth embodiment will be described with reference to FIG. 12. In the fifth embodiment, a component connected to a first protection circuit 430 differs from that in the fourth embodiment. Configurations, operations, and effects similar to those of the fourth embodiment may not be described.

As illustrated in FIG. 12, the first protection circuit 430 is connected to a first gate driver line 416α and an island electrode 37 and is not connected to the common electrode 28. The island electrode 37 is not connected to conductive components such as other lines and electrodes and is electrically isolated. If ESD is input to a first gate driver terminal 429α and a high voltage caused by the ESD is input to the first protection circuit 430, electrostatic breakdown may occur in the first protection circuit 430. If so, the first gate driver line 416α and the island electrode 37 may have a same potential via the first protection circuit 430 having the electrostatic breakdown. In this respect, the island electrode 37 is electrically isolated and any specific signal (potential) is not input to the island electrode 37 from other lines or electrodes. Therefore, even with a short circuit being caused between the first gate driver line 416α and the island electrode 37, a potential different from that of the first gate driver line 416α is less likely to be input to the first gate driver line 416α from the island electrode 37. Thus, unnecessary potential change is less likely to occur in the first gate driver line 416α.

As previously described, according to this embodiment, the island electrode 37 that is electrically isolated corresponds to the first electrode that is connected to the first protection circuit 430. If ESD is input to the first gate driver terminal 429α and the high voltage caused by the ESD is input to the first protection circuit 430, electrostatic breakdown may occur in the first protection circuit 430. If so, the first gate driver line 416α and the island electrode 37 (the first electrode) may have a same potential; however, a potential different from that of the first gate driver line 416α is less likely to be input to the island electrode 37 (the first electrode), which is electrically isolated. Therefore, unnecessary potential change is less likely to occur in the first gate driver line 416α.

### Sixth Embodiment

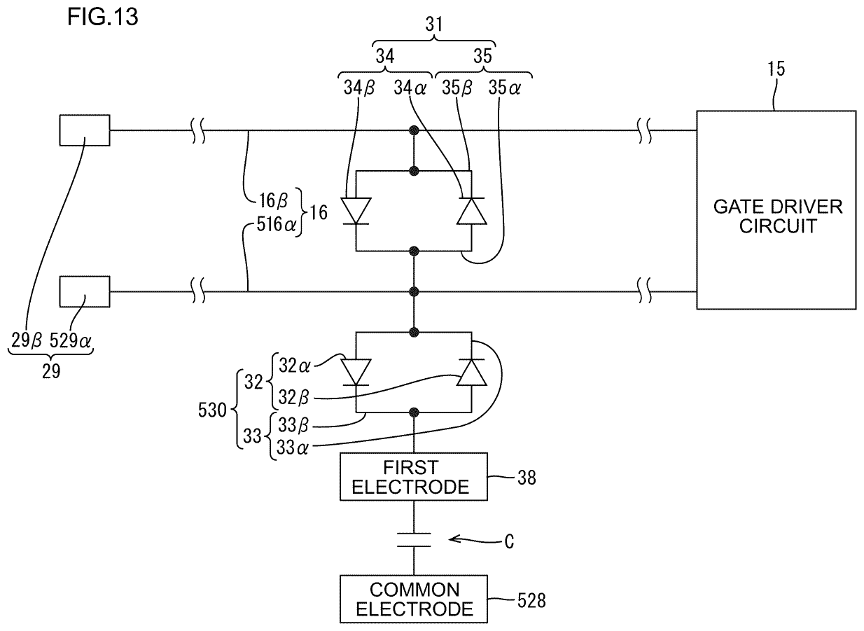

A sixth embodiment will be described with reference to FIG. 13. In the sixth embodiment, a component connected to a first protection circuit 530 differs from that in the fourth embodiment. Configurations, operations, and effects similar to those of the fourth embodiment may not be described.

As illustrated in FIG. 13, the first protection circuit 530 of this embodiment is connected to a first gate driver line 516α and a first electrode 38. The first electrode 38 is disposed opposite and spaced from a common electrode 528 (a second electrode) that is kept at a common potential such that an electrostatic capacitance is created between the first electrode 38 and the common electrode 528. Namely, the first electrode 38 and the common electrode 528 are connected to a condenser C that creates an electrostatic capacitance. One of the electrodes of the condenser C is the first electrode 38 and the other one of the electrodes of the condenser C is the common electrode 528.

If ESD is input to a first gate driver terminal 529α and a high voltage caused by the ESD is input to the first protection circuit 530, electrostatic breakdown may occur in the first protection circuit 530. If so, the first gate driver line 516α and the first electrode 38 may have a same potential via the first protection circuit 530 having the electrostatic breakdown. In this respect, the first electrode 38 and the common electrode 528 are connected to the condenser C and an electrostatic capacitance is created between the first electrode 38 and the common electrode 528. Therefore, even with a short circuit being caused between the first gate driver line 516α and the first electrode 38, a potential different from that of the first gate driver line 516α is less likely to be input to the first electrode 38. Thus, unnecessary potential change is less likely to occur in the first gate driver line 516α.

As previously described, this embodiment includes the common electrode 528 (the second electrode) that is maintained at a predefined potential and the condenser C that is connected to the first electrode 38 and the common electrode 528. If ESD is input to the first gate driver terminal 529α and a high voltage caused by the ESD is input to the first protection circuit 530, electrostatic breakdown may occur in the first protection circuit 530. If so, the first gate driver line 516α and the first electrode 38 may have a same potential; however, the first electrode 38 and the common electrode 528 are connected to the condenser C and an electrostatic capacitance is created between the first electrode 38 and the common electrode 528. Therefore, a potential different from that of the first gate driver line 516α is less likely to be input to the first electrode 38. Thus, unnecessary potential change is less likely to occur in the first gate driver line 516α.

### Seventh Embodiment

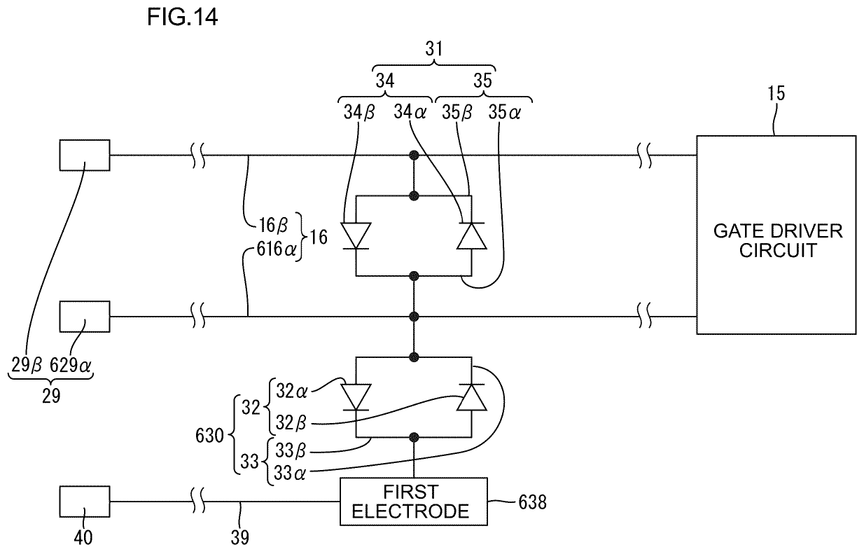

A seventh embodiment will be described with reference to FIG. 14. In the seventh embodiment, a component connected to a first protection circuit 630 differs from that in the fourth embodiment. Configurations, operations, and effects similar to those of the fourth embodiment may not be described.

As illustrated in FIG. 14, the first protection circuit 630 of this embodiment is connected to a first gate driver line 616α and a first electrode 638. The first electrode 638 is connected to a first electrode line 39 that is disposed on the array substrate 21. The first electrode line 39 extends from the first electrode 638 to the mount area of the driver 12 (refer to FIG. 1). An end of the first electrode line 39 that is an opposite end connected to the first electrode 638 is connected to a first electrode terminal 40 (a second terminal) that is disposed in the mount area of the driver 12. With the driver 12 being mounted on the array substrate 21, the first electrode terminal 40 is connected to the bump of the driver 12 via the anisotropic conductive film. A predefined signal is input to the first electrode terminal 40 from the driver 12 and the signal is same as the signal input to a first gate driver terminal 629α. Namely, the same signal is supplied to the first gate driver terminal 629α and the first electrode terminal 40.

If ESD is input to the first gate driver terminal 629α and a high voltage caused by the ESD is input to the first protection circuit 630, electrostatic breakdown may occur in the first protection circuit 630. If so, the first gate driver line 616α and the first electrode 638 may have a same potential via the first protection circuit 630 having the electrostatic breakdown. In this respect, the same signal is input to the first gate driver terminal 629α and the first electrode terminal 40 that is connected to the first electrode 638. Therefore, even with a short circuit being caused between the first gate driver line 616α and the first electrode 638, unnecessary potential change is less likely to occur in the first gate driver line 616α.

As previously described, this embodiment includes the first electrode terminal 40 (the second terminal) connected to the first electrode 638 and the first electrode terminal 40 is supplied with the same signal that is supplied to the first gate driver terminal 629α. If ESD is input to the first gate driver terminal 629α and a high voltage caused by the ESD is input to the first protection circuit 630, electrostatic breakdown may occur in the first protection circuit 630. If so, the first gate driver line 616α and the first electrode 638 may have a same potential; however, the same signal is input to the first gate driver terminal 629α and the first electrode terminal 40 that is connected to the first electrode 638. Therefore, unnecessary potential change is less likely to occur in the first gate driver line 616α.

### Other Embodiments

The technology described herein is not limited to the embodiments described above and illustrated by the drawings. For example, the following embodiments will be included in the technical scope of the present technology.
(1) A plurality of second protection circuits 31, 131, 231, 331 may be included. Specifically, with three or more gate driver lines 16 being arranged at intervals, two or more second protection circuits 31, 131, 231, 331 may be disposed between the adjacent gate driver lines 16. Among the three or more gate driver lines 16, the gate driver line 16 (the second gate driver line 16β, 316β) other than the first gate driver line 16α, 116α, 316α, 416α, 516α, 616α that is connected to one of the common electrode 28, 328, 528, the island electrode 37, and the first electrode 38, 638 via the first protection circuit 30, 130, 230, 330, 430, 530, 630 is configured as the first conductive portion.
(2) Other than the gate driver line 16, the protection circuit 30, 31, 130, 131, 230, 231, 330, 331, 430, 530, 630 may be connected to an auxiliary line (a repair line, a redundant line) disposed for repairing the source line 27.
(3) The second protection circuit 31, 131, 231, 331 may be connected to the first gate driver line 16α, 116α, 316α, 416α, 516α, 616α and a predefined electrode (the first conductive portion).
(4) In the configuration of the first embodiment to the fourth embodiment, the first protection circuit 30, 130, 230, 330 may be directly connected to the common electrode 28, 328.
(5) In the configuration of the first embodiment to the fourth embodiment, the first protection circuit 30, 130, 230, 330 may not be connected to the common line 17, 317 but connected to other line or other electrode that is connected to the common electrode 28, 328.
(6) In the configuration of the second embodiment, the number of connection portions of the first gate driver line 116α that are connected to the first connection line 133α of the first protection circuit 130 may be two, four or more. The second connection line 135α of the second protection circuit 131 may be connected to two portions or more of the first gate driver line 116α.
(7) In the configuration of the third embodiment, the number of first protection circuit components 232 may be six or more.
(8) In the configuration of the fourth embodiment, the channel length L1 of the first thin film transistor 332α and the second thin film transistor 332β may be same as the channel length L2 of the third thin film transistor 334α and the fourth thin film transistor 334β. The channel width W1 of the first thin film transistor 332α and the second thin film transistor 332β may be same as the channel width W2 of the third thin film transistor 334α and the fourth thin film transistor 334β.
(9) In the configuration of the sixth embodiment, the first electrode 38 and the common electrode 528 may be disposed to be directly opposed to each other and configured as the condenser C.
(10) In the configuration of the sixth embodiment, other than the common electrode 528, an electrode that is kept at a low-level potential (Vgl) with the scan signal may be used as the second electrode that is connected to the condenser C.
(11) The configurations of any of the first embodiment to the seventh embodiment may be combined as appropriate.
(12) The gate driver terminal 29 may be disposed in the mount area of the flexible substrate 13. The gate driver terminal 29 may be supplied with signals from the flexible substrate 13.
(13) The opposed substrate 20 and the array substrate 21, 321 may include a resin substrate made of synthetic resin as the light transmissive substrate other than the glass substrate.
(14) The driver 12 may be mounted on the flexible substrate 13 through the chip-on-film (COF) technology. The flexible substrate 13 is mounted on the array substrate 21, 321 through the film-on-glass (FOG) technology.
(15) The planar shape of the liquid crystal panel 11 may be vertically long rectangle, a square, a circle, a semicircle, a vertically long oval, an oval, or a trapezoid.
(16) The display mode of the liquid crystal panel 11 may be the FFS (fringe field switching) mode, the TN (twisted nematic) mode, the VA (vertical alignment) mode, and the IPS (in-plane switching) mode.
(17) Display panels other than the liquid crystal panel 11 such as organic electro luminescence (EL) display panels and microcapsule-based electrophoretic display (EPD) panels may be used as the display device.

1. A wiring substrate comprising:
a first line;
a first terminal connected to an end of the first line;
a first electrode;
a first conductive portion;
a first protection circuit connected to the first line and the first electrode; and
a second protection circuit connected to the first line and the first conductive portion, wherein
a first resistance value that is a total of a line resistance from the first terminal to the first protection circuit and a circuit resistance of the first protection circuit is smaller than a second resistance value that is a total of a line resistance from the first terminal to the second protection circuit and a circuit resistance of the second protection circuit.

2. The wiring substrate according to claim 1, wherein
the first protection circuit is connected to a first connection portion of the first line and the second protection circuit is connected to a second connection portion of the first line, and
the first connection portion is closer to the first terminal than the second connection portion is.

3. The wiring substrate according to claim 1, wherein the number of connection portions of the first protection circuit and the first line is greater than the number of connection portions of the second protection circuit and the first line.

4. The wiring substrate according to claim 1, wherein
the first protection circuit includes first protection circuit components and the second protection circuit includes second protection circuit components, and
the number of the first protection circuit components is greater than the number of the second protection circuit components.

5. The wiring substrate according to claim 1, wherein
the first protection circuit includes a first protection circuit component and the second protection circuit includes a second protection circuit component,
the first protection circuit component includes a first thin film transistor and a second thin film transistor,
the first thin film transistor includes a gate electrode and a source electrode that are connected to the first line and a drain electrode that is connected to the first electrode,
the second thin film transistor includes a gate electrode and a source electrode that are connected to the first electrode and a drain electrode that is connected to the first line,
the second protection circuit component includes a third thin film transistor and a fourth thin film transistor,
the third thin film transistor includes a gate electrode and a source electrode that are connected to the first line and a drain electrode that is connected to the first conductive portion,
the fourth thin film transistor includes a gate electrode and a source electrode that are connected to the first conductive portion and a drain electrode that is connected to the first line, and
the first thin film transistor and the second thin film transistor have a channel width greater than a channel width of the third thin film transistor and the fourth thin film transistor or the first thin film transistor and the second thin film transistor have a channel length smaller than a channel length of the third thin film transistor and the fourth thin film transistor.

6. The wiring substrate according to claim 1, wherein the first electrode is an island electrode that is electrically isolated.

7. The wiring substrate according to claim 1, further comprising:
a second electrode that is kept at a predefined potential; and
a condenser connected to the first electrode and the second electrode.

8. The wiring substrate according to claim 1, further comprising a second terminal that is connected to the first electrode and is supplied with a same signal as a signal that is supplied to the first terminal.

9. A display device comprising:
the wiring substrate according to claim 1; and
an opposed substrate disposed to face the wiring substrate.
